(19) United States
(12) Patent Application Publication
(10) Pub. No.: US 2010/0188376 A1
(43) Pub. Date: Jul. 29, 2010

(54) Display device

(75) Inventors: Hiroshi Sagawa, Kanagawa (JP); Asuka Terai, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/654,569

(22) Filed: Dec. 23, 2009

(30) Foreign Application Priority Data
Dec. 24, 2008 (JP) 2008-328161

(51) Int. Cl. G09G 5/00; H01J 1/62

(52) U.S. Cl. 345/205; 313/504

(57) ABSTRACT

The present invention provides a display device capable of displaying more excellent display performance. A display device has a plurality of light emitting elements arranged on a substrate and obtained by stacking a first electrode layer, an organic layer including a light emitting layer, and a second electrode layer in order; and an insulating film for isolating the organic layer by the light emitting elements. The insulating film has a layer stack structure in which a first layer and a second layer having a refractive index higher than that of the first layer are alternately stacked.

### BACKGROUND OF THE INVENTION

1. Field of the Invention

The present invention relates to a display device having a self-luminous light emitting element including an organic layer.

2. Description of the Related Art

In recent years, as a display device replacing a liquid crystal display, an organic EL display using a self-luminous organic light emitting element including an organic layer has been practically used. An organic EL display is of a light emitting type, so that the angle of view is wider than that of liquid crystal, and response to a high-precision high-speed video signal is sufficiently high.

Attempts to improve the display performance of an organic light emitting element have been being made by controlling light generated by a light emitting layer by, for example, introducing a resonator structure, improving color purity of a light emitting color, or increasing light emitting efficiency as described in, for example, WO 01/39554. For example, in a top emission type of extracting light from the face opposite to the substrate (the top face), on the substrate, an anode electrode, an organic layer, and a cathode electrode are stacked in order via a drive transistor, and light from the organic layer is multiply reflected between the anode electrode and the cathode electrode.

### SUMMARY OF THE INVENTION

However, all of light whose intensity is increased between the anode electrode and the cathode electrode is not emitted from the top face but a part of the light enters as stray light between the substrate and the anode electrode. Sometimes it is incident on the channel region of the drive transistor. In such a case, erroneous operation occurs in the drive transistor, and a video image in which a predetermined video signal is faithfully reflected may not be obtained. There is also the possibility that the life of the drive transistor is shortened.

It is therefore desirable to provide a display device capable of displaying more excellent display performance.

According to an amendment of the present invention, a first display device having: a plurality of light emitting elements arranged on a substrate and obtained by stacking a first electrode layer, an organic layer including a light emitting layer, and a second electrode layer in order; and an insulating film for isolating the organic layer by the light emitting elements. The insulating film has a layer stack structure in which a first layer and a second layer having a refractive index higher than that of the first layer are alternately stacked.

In the first display device of the embodiment of the present invention, the insulating film that isolates the organic layers of neighboring light emitting elements is obtained by alternately stacking first and second layers having different refractive indices. Consequently, component light leaked to the insulating film in light which is emitted from the organic layer and is multiply reflected between the first and second electrode layers is reflected by the insulating film and attenuated, or is not leaked to the outside and returns to the organic layer.

According to an embodiment of the present invention, a second display device including: a plurality of light emitting elements disposed on a substrate and obtained by stacking a first electrode layer, an organic layer including a light emitting layer, and a second electrode layer in order; a drive transistor provided in a layer between the substrate and the light emitting element and performing display driving of the light emitting element on the basis of a video signal; and an insulating film provided between the drive transistor and the light emitting element. The insulating film has a layer stack structure in which a first layer and a second layer having a refractive index higher than that of the first layer are alternately stacked.

In the second display device of the embodiment of the present invention, the insulating film provided between the light emitting elements and the drive transistor for driving the light emitting element is obtained by alternately stacking first and second layers having different refractive indices. Consequently, component light leaked to the insulating film in light which is emitted from the organic layer and is multiply reflected between the first and second electrode layers is reflected by the insulating film and attenuated without entering the drive transistor.

In the first display device of the embodiment of the present invention, the insulating film that isolates the organic layers of the light emitting elements has the structure obtained by alternately stacking two kinds of optical films having different refractive indices, so that component light leaked from the light emitting elements to the insulating film in the periphery may be returned to the organic layer. Therefore, the light emitting efficiency of the light emitting elements may be increased, and power consumption may be reduced.

In the second display device of the embodiment of the present invention, the insulating film having the structure in which two kinds of optical films having different refractive indices are alternately stacked is provided between the drive transistor and the light emitting element, so that component light leaked from the light emitting element to the periphery may be prevented from entering the channel region of the drive transistor and the like. Therefore, occurrence of leak current to the pixel drive circuit caused by erroneous operation in the drive transistor is prevented with reliability, and the picture quality may be improved. In addition, deterioration in life of the drive transistor is prevented, and the operation reliability may be increased.

Other and further objects, features and advantages of the invention will appear more fully from the following description.

### BRIEF DESCRIPTION OF THE DRAWINGS

FIG. 1 is a diagram illustrating the configuration of a display device according to an embodiment of the present invention.

FIG. 2 is a diagram illustrating an example of a pixel drive circuit shown in FIG. 1.

FIG. 3 is a plan view illustrating the configuration of a display region shown in FIG. 1.

FIGS. 4A and 4B are a cross sections illustrating the configuration of the display region shown in FIG. 1.

FIG. 5 is a cross section illustrating the configuration of an organic light emitting element shown in FIG. 3.

FIG. 6 is another cross section illustrating the configuration of the organic light emitting element shown in FIG. 3.

FIG. 7 is a plan view illustrating the configuration of a pixel drive circuit formation layer shown in FIGS. 5 and 6.

FIG. 8 is an enlarged cross section of an organic layer illustrated in FIG. 5.

### DETAILED DESCRIPTION OF THE PREFERRED EMBODIMENTS

Embodiments of the present invention will be described in detail with reference to the drawings.

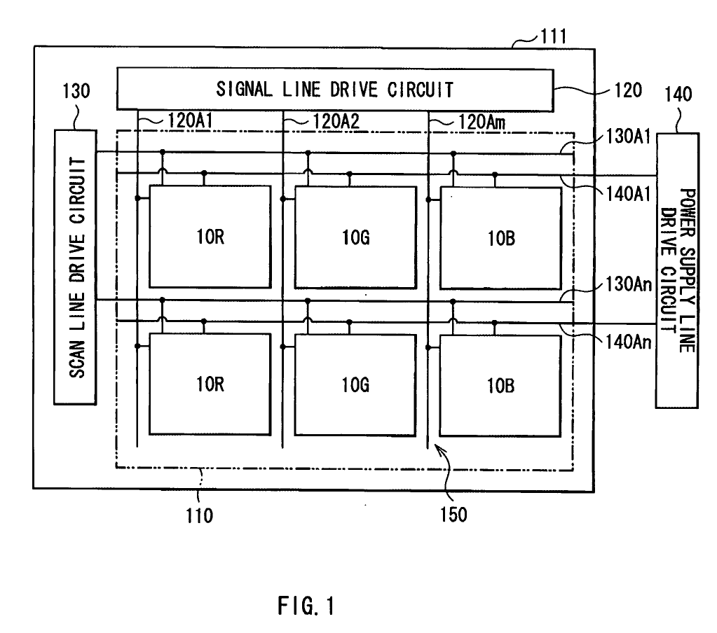

FIG. 1 illustrates the configuration of a display device using an organic light emitting element according to an embodiment of the present invention. The display device is used as an ultrathin organic light emitting color display device or the like. In the display device, a display region 110 is formed on a substrate 111. In the periphery of the display region 110 on the substrate 111, for example, a signal line drive circuit 120, a scan line drive circuit 130, and a power supply line drive circuit 140 as drivers for displaying a video image are formed.

In the display region 110, a plurality of organic light emitting elements 10 (10R, 10G, and 10B) which are two-dimensionally disposed in matrix and a pixel drive circuit 150 for driving the elements 10 are formed. In the pixel drive circuit 150, a plurality of signal lines 120A (120A1, 120A2, . . . , 120Am, . . . ) are disposed in the column direction, and a plurality of scan lines 130A (130A1, . . . 130An, . . . ) and a plurality of power supply lines 140A (140A1, . . . 140An, . . . ) are disposed in the row direction. Any one of the organic light emitting elements 10R, 10G, and 10B is provided in correspondence with the cross point between the signal line 120A and the scan line 130A. The signal lines 120A are connected to the signal line drive circuit 120, the scan lines 130A are connected to the scan line drive circuit 130, and the power supply lines 140A are connected to the power supply line drive circuit 140.

The signal line drive circuit 120 supplies a signal voltage of a video signal according to brightness information supplied from a signal supply source (not shown) to the selected organic light emitting element 10R, 10G, or 10B via the signal line 120A.

The scan line drive circuit 130 is constructed by, for example, a shift register that sequentially shifts (transfers) a start pulse synchronously with an input clock pulse. The scan line drive circuit 130 scans the organic light emitting elements 10R, 10G, and 10B row by row at the time of writing a video signal to the organic light emitting elements 10R, 10G, and 10B, and sequentially supplies the scan signal to the scan lines 130A.

The power supply line drive circuit 140 is constructed by, for example, a shift register that sequentially shifts (transfers) a start pulse synchronously with an input clock pulse. The power supply line drive circuit 140 properly supplies any of first and second potentials which are different from each other to a power supply line 140A synchronously with the row-by-row scan of the scan line drive circuit 130. Accordingly, a conduction state or a non-conduction state of a drive transistor Tr1 which will be described later is selected.

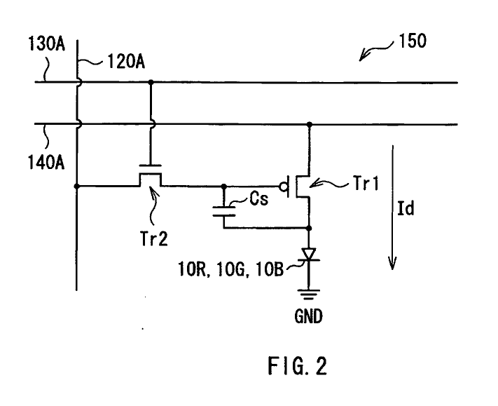

The pixel drive circuit 150 is provided in a layer (a pixel drive circuit formation layer 112 which will be described later) between the substrate 111 and the organic light emitting element 10. FIG. 2 illustrates a configuration example of the pixel drive circuit 150. As shown in FIG. 2, the pixel drive circuit 150 is an active-type drive circuit having the drive transistor Tr1, a write transistor Tr2, a capacitor (retention capacitor) Cs provided between the transistors Tr1 and Tr2, and the organic light emitting element 10. The organic light emitting element 10 is connected in series with the drive transistor Tr1 between the power supply line 140A and a common power supply line (GND). The drive transistor Tr1 and the write transistor Tr2 are general thin film transistors (TFTs) and may have, for example, an inverted staggered structure (so-called bottom gate type) or a staggered structure (top gate type), and structures are not limited, especially.

For example, the drain electrode of the write transistor Tr2 is connected to the signal line 120A, and the video signal from the signal line drive circuit 120 is supplied to the write transistor Tr2. The gate electrode of the write transistor Tr2 is connected to the scan line 130A, and the scan signal from the scan line drive circuit 130 is supplied to the write transistor Tr2. Further, the source electrode of the write transistor Tr2 is connected to the gate electrode of the drive transistor Tr1.

For example, the drain electrode of the drive transistor Tr1 is connected to the power supply line 140A and is set to either the first or second potential by the power supply line drive circuit 140. The source electrode of the drive transistor Tr1 is connected to the organic light emitting element 10.

The retention capacitor Cs is formed between the gate electrode of the drive transistor Tr1 (the source electrode of the write transistor Tr2) and the source electrode of the drive transistor Tr1.

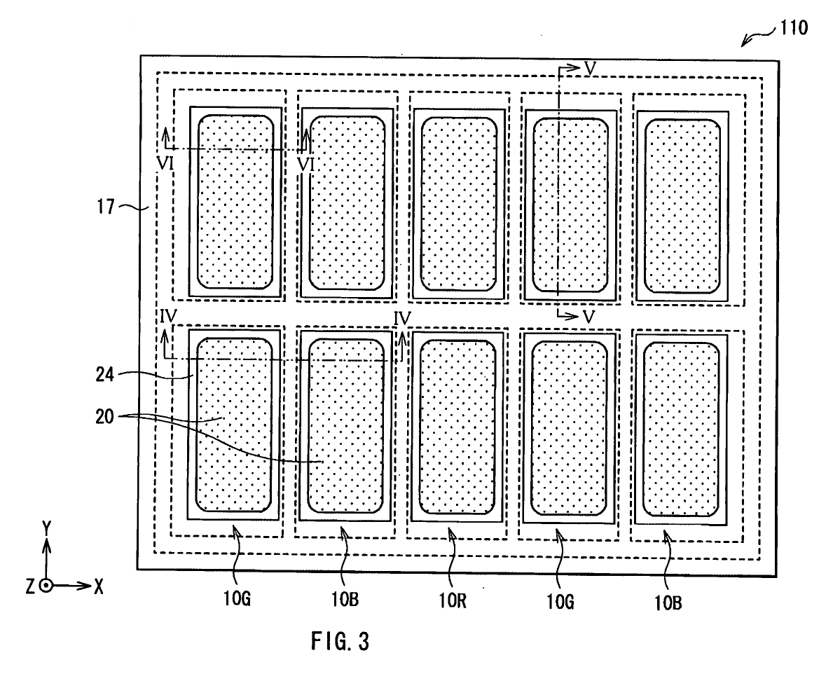

FIG. 3 illustrates a configuration example of the display region 110 extending in an XY plane. In the display region 110, a plurality of organic light emitting elements 10 are disposed in order in a matrix as a whole. More specifically, a metal layer 17 as an auxiliary electrode layer is provided in a lattice shape. In each of regions defined by the metal layer 17, any of the organic light emitting elements 10R, 10G, and 10B each including a light emitting region 20 whose contour is defined by an opening defining insulting film 24 is disposed. The organic light emitting element 10R emits red light, the organic light emitting element 10G emits green light, and the organic light emitting element 10B emits blue light. In this case, the organic light emitting elements 10 that emit light of the same color are arranged in one line in the Y direction, and the arrangement is repeated in order in the X direction. Therefore, one pixel is constructed by a combination of the organic light emitting elements 10R, 10G, and 10B which are neighboring in the X direction. In FIG. 3, the lattice-shaped regions expressed by broken lines are regions in which the metal layer 17 and a second electrode layer 16 (which will be described later) are electrically connected to each other. Although FIG. 3 illustrates total 10 pieces of organic light emitting elements 10 which are in two rows and in five columns, the number is not limited to ten.

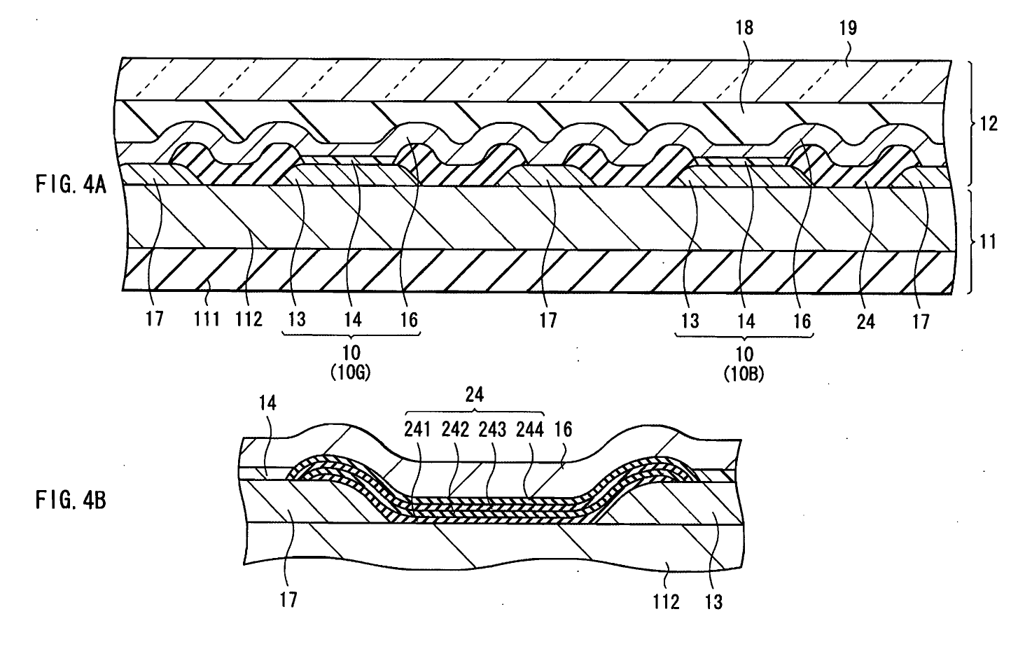

FIG. 4A illustrates a schematic configuration in an XZ section taken along line IV-IV of FIG. 3, in the display region 110. FIG. 4B illustrates a partly-enlarged view of FIG. 4A. As illustrated in FIG. 4A, in the display region 110, a light emitting element formation layer 12 including the organic light emitting element 10 is formed on a base 11 obtained by providing the substrate 111 with a pixel drive circuit formation layer 112. Over the organic light emitting element 10, a protection film 18 and a sealing substrate 19 are provided in order. The organic light emitting element 10 is obtained by sequentially stacking, from the side of the substrate 111, a first electrode layer 13 as an anode electrode, an organic layer 14 including a light emitting layer 14C (which will be described later), and the second electrode layer 16 as a cathode electrode. The organic layer 14 and the first electrode layer 13 are isolated from each other by the opening defining insulating film 24 by the organic light emitting elements 10. On the other hand, the second electrode layer 16 is provided commonly for all of the organic light emitting elements 10. The metal layer 17 is electrically connected to the second electrode layer 16 so as to isolate the opening defining insulting film 24 by the organic light emitting elements 10. In FIGS. 4A and 4B, the detailed configurations of the drive transistor Tr1, the write transistor Tr2, and the like in the pixel drive circuit formation layer 112 are not illustrated.

The opening defining insulating film 24 is provided so as to cover the end faces of the first electrode layer 13 and the top face of the peripheral part and bury the spaces between the first electrode layer 13 and the organic layer 14 and the metal layer 17. The opening defining insulating film 24 has a four-layer structure in which low-refractive-index layers 241 and 243 having a refractive index N_{L} and high-refractive-index layers 242 and 244 having a refractive index N_{H} (>N_{L}) are stacked alternately. The low-refractive-index layers 241 and 243 are made of at least one of, for example, silicon oxide (SiO₂), aluminum fluoride (AlF₃), calcium fluoride (CaF₂), cerium fluoride (CeF₃), lanthanum fluoride (LaF₃), lithium fluoride (LiF), magnesium fluoride (MgF₂), neodymium fluoride (NdF₃), and sodium fluoride (NaF). On the other hand, the high-refractive-index layers 242 and 244 are made of at least one of, for example, silicon nitride (Si₃N₄), aluminum oxide (Al₂O₃), chromium oxide (Cr₂O₃), gallium oxide (Ga₂O₃), hafnium oxide (HfO₂), nickel oxide (NiO), magnesium oxide (MgO), indium tin oxide (ITO), lanthanum oxide (La₂O₃), niobium oxide (Nb₂O₅), tantalum oxide (Ta₂O₅), yttrium oxide (Y₂O₃), tungsten oxide (WO₃), titanium monoxide (TiO), titanium dioxide (TiO₂), and zirconium oxide (ZrO₂). It is desirable to design the thickness (N×D where N denotes refractive index with respect to “d” line, and D denotes physical film thickness) of each of optical films constructing the opening defining insulating film 24 to be 0.25 time of wavelength λo (=630 nm) of visible light. That is, the physical film thickness D_{L} of the low-refractive-index layers 241 and 243 is preferably a value obtained by dividing λo/4 (=157.5 nm) by N_{L}. Similarly, the physical film thickness D_{H} of the high-refractive-index layer 242 is preferably a value obtained by dividing λo/4 (=157.5 nm) by N_{H}. The opening defining insulating film 24 having such a stack-layer structure functions to reflect light generated in the light emitting layer 14C in the organic layer 14 and leaked from the end face of the organic layer 14, attenuate, or return the light to the organic layer 14 without being leaked to the outside. Further, the opening defining insulating film 24 assures insulation between the first and second electric layers 13 and 16 and the metal layer 17, and accurately forms a light emitting region 20 in the organic light emitting element 10 in a desired shape.

The protection film 18 covering the organic light emitting element 10 is made of an insulating material such as silicon nitride (SiNx) or the like. The sealing substrate 19 which is provided on the protection film 18 seals the organic light emitting element 10 together with the protection film 18, an adhesive layer (not shown), and the like and is made of a material such as transparent glass which transmits light generated in the light transmission layer 14C.

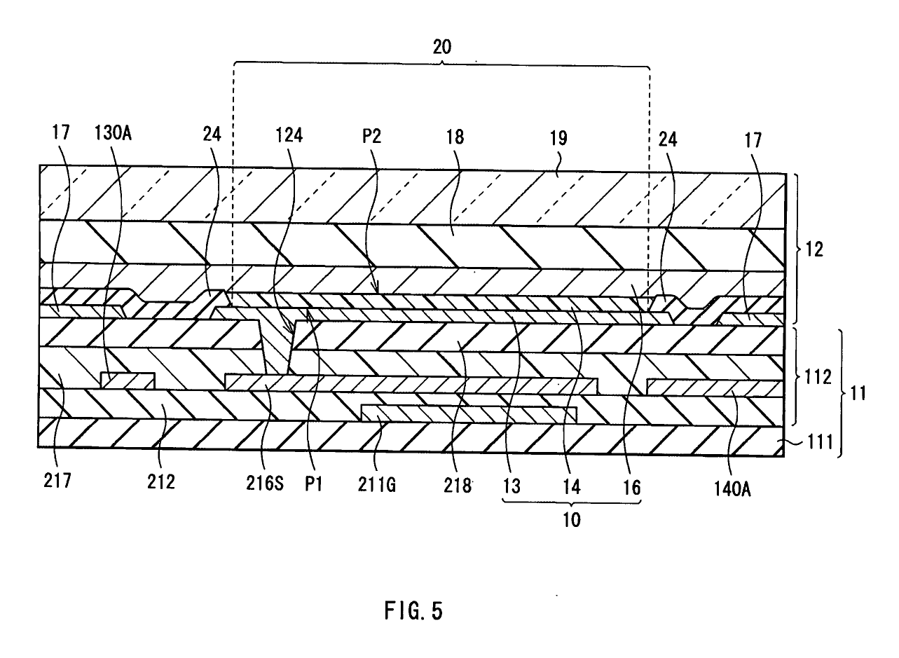

Referring now to FIGS. 5 to 8, the detailed configuration of the base 11 and the organic light emitting element 10 will be described. Since the organic light emitting elements 10R, 10G, and 10B have a similar configuration except that the configuration of the organic layer 14 partly varies, they will be described generically in the following.

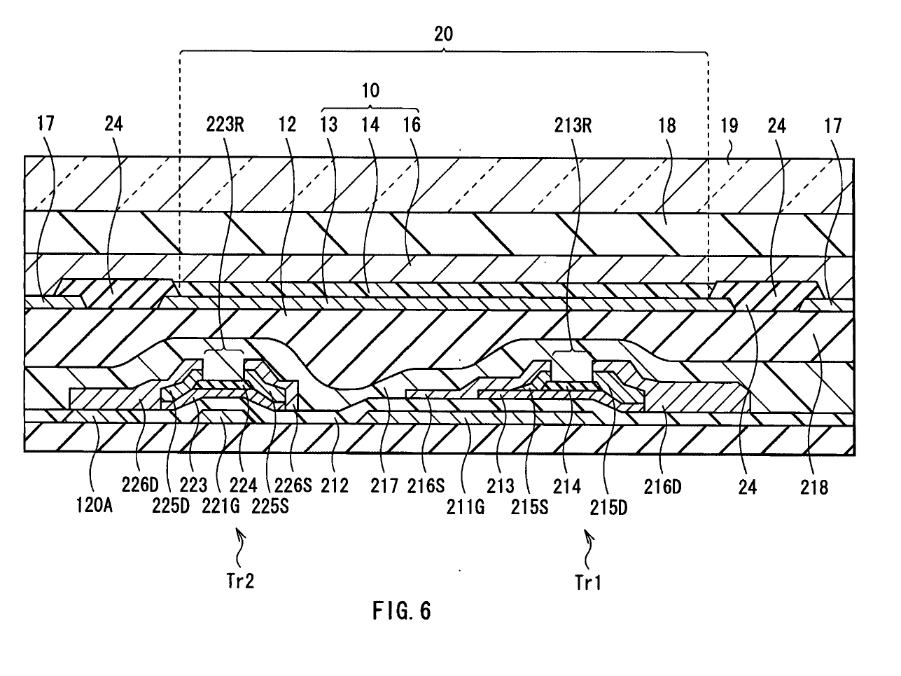

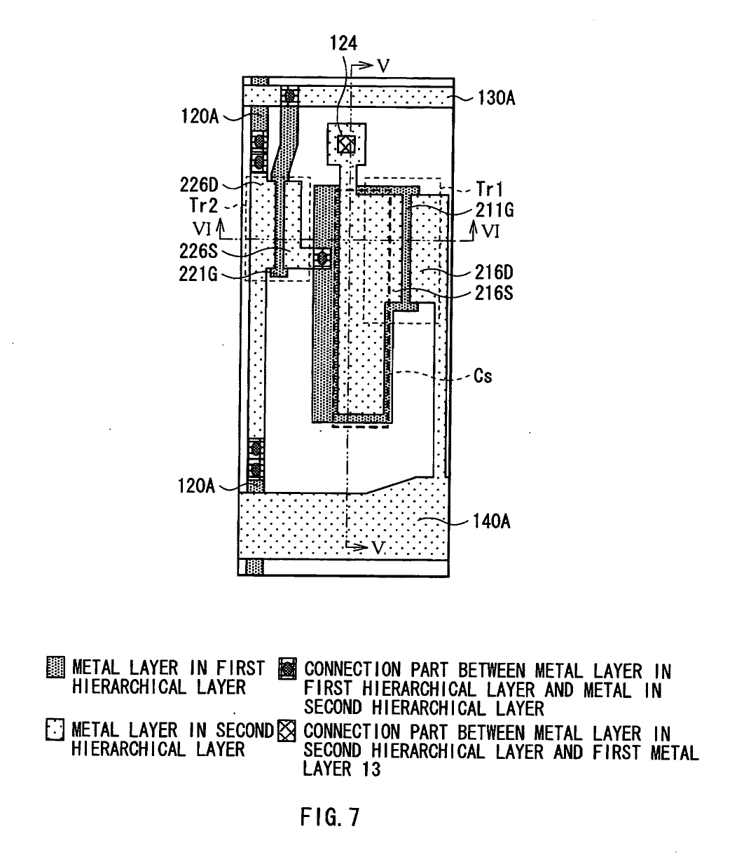

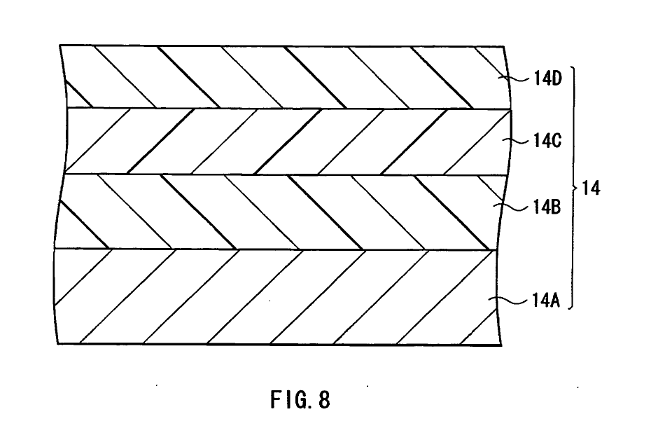

FIG. 5 is a cross section taken along line V-V, of the display region 110 illustrated in FIG. 3. FIG. 6 is a cross section taken along line VI-VI illustrated in FIG. 3. FIG. 7 is a schematic diagram illustrating a plane configuration of the pixel drive circuit 150 provided for the pixel drive circuit formation layer 112, in an organic light emitting element 10. Further, FIG. 8 is a partly-enlarged section of the organic layer 14 illustrated in FIGS. 4 to 6. FIG. 5 corresponds to the section taken along line V-V illustrated in FIG. 7. FIG. 6 corresponds to the section taken along line VI-VI illustrated in FIG. 7.

The base 11 is obtained by providing the substrate 111 which is a glass or silicon (Si) wafer or made of resin with the pixel drive circuit formation layer 112 including the pixel drive circuit 150. On the surface of the substrate 111, as metal layers in a first hierarchical layer, a metal layer 211G as the gate electrode of the drive transistor Tr1, a metal layer 221G as the gate electrode of the write transistor Tr2, and the signal line 120A (FIGS. 6 and 7) are provided. The metal layers 211G and 221G and the signal line 120A are covered with a gate insulating film 212 made of silicon nitride, silicon oxide, or the like. In regions corresponding to the metal layers 211G and 221G on the gate insulting film 212, channel layers 213 and 223 as semiconductor thin films made of amorphous silicon or the like are provided. On the channel layers 213 and 223, channel protection films 214 and 224 having insulation property are provided so as to occupy channel regions 213R and 223R as center regions of the channel layers 213 and 223, respectively. In regions on both sides of the channel protection film 214, a drain electrode 215D and a source electrode 215S made by an n-type semiconductor thin film made of n-type amorphous silicon or the like are provided. In regions on both sides of the channel protection film 224, a drain electrode 225D and a source electrode 225S made by the n-type semiconductor thin film made of n-type amorphous silicon or the like are provided. The drain electrodes 215D and 225D and the source electrodes 215S and 225S are isolated from each other by the channel protection films 214 and 224, respectively, and their end faces are apart from each other while sandwiching the channel regions 213R and 223R. Further, metal layers 216D and 226D as drain wires and metal layers 216S and 226S as source wires are provided as metal layers in the second hierarchical layer so as to cover the drain electrodes 215D and 225D and the source electrodes 215S and 225S, respectively. The metal layers 216D and 226D and the metal layers 216S and 226S have a structure obtained by sequentially stacking, for example, a titanium (Ti) layer, an aluminum (Al) layer, and a titanium layer. As the metal layers in the second hierarchical layer, in addition to the metal layers 216D and 226D and the metal layers 216S and 226S, the scan line 130A and the power supply line 140A (FIGS. 5 and 7) are provided. Although the drive transistor Tr1 and the write transistor Tr2 having the inverted staggered structure (so-called bottom-gate type) have been described, transistors having a staggered structure (so-called top-gate type) are also possible. The signal line 120A may be provided in the second hierarchical layer in the region other than the cross point between the scan line 130A and the power supply line 140A.

The pixel drive circuit 150 is covered with a protection film (passivation film) 217 made of silicon nitride or the like. A planarization film 218 having insulating property is provided on the protection film 217. The surface of the planarization film 218 is desired to have extremely high flatness. A fine connection hole 124 is provided in a partial region in the planarization film 218 and the protection film 217 (refer to FIGS. 5 and 7). Since the planarization film 218 is thicker than the protection film 217, preferably, the planarization film 218 is made of a material having high pattern precision such as an organic material, for example, polyimide. The connection hole 124 is filled with the first electrode layer 13.

The first electrode layer 13 formed on the planarization film 218 also functions as a reflection layer and is desirably made of a material having reflectance as high as possible from the viewpoint of increasing light emitting efficiency. The first electrode layer 13 has a thickness of, for example, 100 nm to 1,000 nm both inclusive and is made of a metal element such as silver (Ag), aluminum (Al), chromium (Cr), titanium (Ti), iron (Fe), cobalt (Co), nickel (Ni), molybdenum (Mo), copper (Cu), tantalum (Ta), tungsten (W), platinum (Pt), neodymium (Nd), or gold (Au) or an alloy of any of the metal elements. In the case of making a metal layer 23 which will be described later of a high-reflectivity material such as aluminum and making the metal layer 23 function as a reflection layer, the first electrode layer 13 may be made of a transparent conductive material such as indium tin oxide (ITO), zinc oxide (ZnO), or tin oxide (SnO₂). The first electrode layer 13 is formed so as to cover the surface of the planarization film 218 and fill the connection hole 124. With the configuration, the first electrode layer 13 is conducted with (the metal layer 216S in) the drive transistor Tr1 via the connection hole 124.

The organic layer 14 is closely formed in the entire light emitting region 20 defined by the opening defining insulating film 24. The organic layer 14 has a configuration, for example, as shown in FIG. 8, in which a hole injection layer 14A, a hole transport layer 14B, the light emitting layer 14C, and an electron transport layer 14D are stacked in order from the side of the first electrode layer 13. The layers other than the light emitting layer 14C may be provided as necessary.

The hole injection layer 14A is a buffer layer for increasing the hole injection efficiency and for preventing leakage. The hole transport layer 14B is provided to increase the efficiency of transporting holes to the light emitting layer 14C. In the light emitting layer 14C, by applying an electric field, recombination of electrons and holes occurs, and light is generated. The electron transport layer 14D is provided to increase the efficiency of transporting electrons to the light emitting layer 14C. An electron injection layer (not shown) made of LiF, Li₂O, or the like may be provided between the electron transport layer 14D and the second electrode 16.

The configuration of the organic layer 14 varies according to the light emitting colors of the organic light emitting elements 10R, 10G, and 10B. The hole injection layer 14A of the organic light emitting element 10R has a thickness of, for example, 5 nm to 300 nm and is made of 4,4′,4″-tris(3-methylphenylamino) triphenylamine (m-MTDATA), or 4,4′,4″-tris(2-naphthylphenylamino) triphenylamine (2-TNATA). The hole transport layer 14B of the organic light emitting element 10R has a thickness of, for example, 5 nm to 300 nm both inclusive and is made of bis[(N-naphthyl)-N-phenyl]benzidine (α-NPD). The light emitting layer 14C of the organic light emitting element 10R has a thickness of, for example, 10 nm to 100 nm both inclusive and is made of a material obtained by mixing 40% by volume of 2,6-bis[4-[N-(4-methoxyphenyl)-N-phenyl]aminostyryl]naphthalene-1,5-dicarbonitrile (BSN-BCN) to 8-quinolinol aluminum complex (Alq₃). The electron transport layer 14D of the organic light emitting element 10R has a thickness of, for example, 5 nm to 300 nm both inclusive and is made of Alq₃.

The hole injection layer 14A of the organic light emitting element 10G has a thickness of, for example, 5 nm to 300 nm both inclusive and is made of m-MTDATA or 2-TNATA. The hole transport layer 14B of the organic light emitting element 10G has a thickness of, for example, 5 nm to 300 nm both inclusive and is made of α-NPD. The light emitting layer 14C of the organic light emitting element 10G has a thickness of, for example, 10 nm to 100 nm both inclusive and is made of a material obtained by mixing 3 volume % of coumarin 6 to Alq₃. The electron transport layer 14D of the organic light emitting element 10G has a thickness of, for example, 5 nm to 300 nm both inclusive and is made of Alq₃.

The hole injection layer 14A of the organic light emitting element 10B has a thickness of, for example, 5 nm to 300 nm both inclusive and is made of m-MTDATA or 2-TNATA. The hole transport layer 14B of the organic light emitting element 10B has a thickness of, for example, 5 nm to 300 nm both inclusive and is made of α-NPD. The light emitting layer 14C of the organic light emitting element 10B has a thickness of, for example, 10 nm to 100 nm both inclusive and is made of spiro 64). The electron transport layer 14D of the organic light emitting element 10B has a thickness of, for example, 5 nm to 300 nm both inclusive and is made of Alq₃.

The second electrode layer 16 has a thickness of, for example, 5 nm to 50 nm and is made of a metal element or an alloy of aluminum (Al), magnesium (Mg), calcium (Ca), sodium (Na) or the like. Particularly, an alloy of magnesium and silver (MgAg alloy) or an alloy of aluminum (Al) and lithium (Li) (AlLi alloy) is preferable. The second electrode layer 16 is provided, for example, commonly to all of the organic light emitting elements 10R, 10G, and 10B and is disposed so as to face the first electrode layer 13 of each of the organic light emitting elements 10R, 10G, and 10B. Further, the second electrode layer 16 is formed so as to cover not only the organic layer 14 but also the opening defining insulating film 24 and the metal layer 17. Therefore, as described above, the second electrode layer 16 is electrically connected to the metal layer 17.

The metal layer 17 is formed on the surface of the planarization film 218 in a manner similar to the first electrode layer 13 and functions as an auxiliary electrode layer for compensating a voltage drop in the second electrode layer 16 as a main electrode. The material of the metal layer 17 is preferably, for example, a metal material having high conductive property like that of the first electrode layer 13. Further, it is desirably to narrow the metal layer 17 as much as possible (to reduce the occupation area) from the viewpoint of improving the aperture ratio.

In the case where the metal layer 17 does not exist, due to a voltage drop according to the distance from the power supply (not shown) to each of the organic light emitting elements 10R, 10G, and 10B, the potential of the second electrode layer 16 connected to the common power supply line GND (refer to FIG. 2) varies among the organic light emitting elements 10R, 10G, and 10B, and considerable variations tend to occur. Such variations in the potential of the second electrode layer 16 are unpreferable since they cause brightness unevenness in the display region 110. The metal layer 17 functions to suppress a voltage drop from the power supply to the second electrode layer 16 to the minimum even in the case where the screen of the display device is enlarged, and to suppress occurrence of such brightness unevenness.

In the organic light emitting element 10, the first electrode layer 13 displays the function of a reflection layer and, on the other hand, the second electrode layer 16 displays the function of a semi-transmissive reflection layer. By the first and second electrode layers 13 and 16, light generated by the light emitting layer 14C included in the organic layer 14 may be multiply-reflected. That is, the organic light emitting element 10 has a resonator structure, using the end face on the organic layer 14 side of the first electrode layer 13 as a first end part P1, using the end face on the organic layer 14 side of the second electrode layer 16 as a second end part P2, and using the organic layer 14 as a resonation part, that resonates light generated by the light emitting layer 14C and extracts the resonated light from the side of the second end part P2. By having such a resonator structure, light generated by the light emitting layer 14C multiply-reflects. The organic light emitting element 10 acts as a kind of a narrowband filter, so that the half bandwidth of spectrum of the light extracted decreases, and color purity may be increased. External light incident from the side of the sealing substrate 19 may be also attenuated by multiple reflection. Further, outside light which is incident from the side of the sealing substrate 19 may be also attenuated by multiple reflection. Further, by combination with a retarder or polarizer (not shown), reflectance of outside light in the organic light emitting element 10 may be extremely decreased.

For example, the display device may be manufactured as follows. A method of manufacturing the display device of the embodiment will be described below with reference to FIGS. 4 to 7.

First, on the substrate 111 made of the above-described material, the pixel drive circuit 150 including the drive transistor Tr1 and the write transistor Tr2 is formed. Concretely, first, a metal film is formed by, for example, sputtering on the substrate 111. After that, by patterning the metal film by, for example, photolithography, dry etching, or wet etching, the metal layers 211G and 221G and the signal line 120A are formed on the substrate 111. Subsequently, the entire surface is covered with the gate insulating film 212. Further, on the gate insulating film 212, the channel layers 213 and 223, the channel protection films 214 and 224, the drain electrodes 215D and 225D, the source electrodes 215S and 225S, the metal layers 216D and 226D, and the metal layers 216S and 226S are sequentially formed in a predetermined shape. Together with formation of the metal layers 216D and 226D and the metal layers 216S and 226S, the scan line 130A and the power supply line 140A are formed as the second metal layer. In this case, a connection part for connecting the metal layer 221G and the scan line 130A, a connection part for connecting the metal layer 226D and the signal line 120A, and a connection part for connecting the metal layers 226S and 211G are formed in advance. After that, by covering the whole with the protection film 217, the pixel drive circuit 150 is completed. In a predetermined position in the metal layer 216S in the protection film 217, an opening is formed by dry etching or the like.

After formation of the pixel drive circuit 150, for example, a photosensitive resin containing polyimide as a main component is applied to the entire surface. By performing the photolithography process on the photosensitive resin, the planarization film 218 having the connection hole 124 is formed. Concretely, for example, by selective exposure and development using a mask having an opening in a predetermined position, the connection hole 124 communication with the opening formed in the protection film 217 is formed. After that, the planarization film 218 may be baked as necessary. In such a manner, the pixel drive circuit formation layer 112 is obtained.

Further, the first electrode layer 13 and the metal layer 17 made of the above-described material are formed in a lump. Concretely, a metal layer made of the above-described material is formed on the entire surface by, for example, sputtering. After that, a resist pattern (not shown) in a predetermined shape is formed by using a predetermined mask on the metal film. Further, using the resist pattern as a mask, the metal film is selectively etched. The first electrode layer 13 is formed so as to cover the surface of the planarization film 218 and so as to fill the connection hole 124. The metal layer 17 is formed on the surface of the planarization film 218 so as to surround the periphery of the first electrode layer 13. Desirably, the metal layer 17 is formed by a material of the same kind as that of the first electrode layer 13. Further, the opening defining insulating film 24 having the multilayer structure is formed so as to fill the gap between the metal layer 17 and the first electrode layer 13.

Subsequently, the hole injection layer 14A, the hole transport layer 14B, the light emitting layer 14C, and the electron transport layer 14D each made of the above-described predetermined material and having the above-described thickness are stacked in order by, for example, the evaporation method so as to completely cover an exposed part in the first electrode layer 13, thereby forming the organic layer 14. Further, by forming the second electrode layer 16 on the entire surface so as to face the first electrode layer 13 over the organic layer 14 and so as to cover the metal layer 17, the organic light emitting element 10 is completed.

After that, the protection film 18 made of the above-described material is formed so as to cover the whole. Finally, an adhesive layer is formed on the protection film 18, and the sealing substrate 19 is adhered while using the adhesive layer therebetween. As a result, the display device is completed.

In the display device obtained in such a manner, a scan signal is supplied from the scan line drive circuit 130 to each pixel via a gate electrode (the metal layer 221G) of the write transistor Tr2, and an image signal from the signal line drive circuit 120 is held at the holding retention Cs via the write transistor Tr2. On the other hand, the power supply line drive circuit 140 supplies a first high potential higher than a second potential to each of the power supply lines 140A synchronously with a scan on the row unit by the scan line drive circuit 130. Accordingly, the conductive state of the drive transistor Tr1 is selected, and a drive current Id is injected to the organic light emitting elements 10R, 10G, and 10B, thereby causing recombination between holes and electrons and generating light. The light is multiply-reflected between the first and second electrode layers 13 and 16, transmits the second electrode layer 16, the protection film 18, and the sealing substrate 19 and is extracted.

As described above, in the embodiment, the opening defining insulating film 24 that isolates the organic layer 14 every organic light emitting element 10 has a layer-stack structure in which the low-refractive-index layers 241 and 243 and the high-refractive-index layers 242 and 244 are alternately stacked, so that the following effect is produced. That is, component light leaked to the opening defining insulating film 24 in the light which is emitted from the organic layer 14 and is multiply-reflected between the first and second electrode layers 13 and 16 is reflected by the opening defining insulating film 24 and attenuated, or is not leaked to the outside and returns again to the organic layer 14. Therefore, the light emitting efficiency of the organic light emitting element 10 may be increased, and power consumption may be reduced.

Since the opening defining insulating film 24 is provided so as to closely fill the region of the gap between the first electrode layer 13 and the metal layer 17 in the hierarchical layer in which the first electrode layer 13 and the metal layer 17 are provided, unnecessary light such as outside light and light leaked from the organic light emitting element 10 may be prevented from entering the channel regions 213R and 223R in the drive transistor Tr1 and the write transistor Tr2 positioned in a lower layer. Therefore, occurrence of leak current to the pixel drive circuit 150 caused by erroneous operation in the drive transistor Tr1 and the write transistor Tr2 is prevented with reliability, and the picture quality may be improved. In addition, deterioration in life of the drive transistor Tr1 and the write transistor Tr2 is prevented, and the operation reliability may be increased.

Although the present invention has been described above by the embodiments, the invention is not limited to the embodiments but may be variously modified. For example, in the foregoing embodiment, the structure of the opening defining insulating film 24 which isolates the organic layer 14 by the organic light emitting elements 10 is the layer-stack structure of the high-refractive-index layer and the low-refractive-index layer. However, the invention is not limited to the embodiment. For example, the protection film 217 covering the drive transistor Tr1 and the write transistor Tr2 or the planarization film 218 on the protection film 217 may have the layer-stack structure. In this case as well, the various materials used for the opening defining insulating film 24 may be used as they are. In such a configuration as well, incidence of unnecessary light to the channel regions 213R and 23R in the drive transistor Tr1 and the write transistor Tr2 may be prevented, and effects such as improvement in picture quality and improvement in long-term reliability are obtained. In particular, when the planarization film 218 closely covering the drive transistor Tr1 and the write transistor Tr2 has the layer-stack structure, it is more effective. In the case where the planarization film 218 has the layer-stack structure, it is sufficient to form the planarization film 218 so as to cover at least the channel regions 213R and 223R in the drive transistor Tr1 and the write transistor Tr2. In such a manner, incidence of unnecessary light to the channel regions 213R and 223R may be reliably prevented without forming the planarization film 218 on the entire surface.

The present invention is not limited to the materials of the layers, the layer stack order, the film forming method, and the like described in the foregoing embodiment. For example, although the opening defining insulating film 24 has the four-layer structure in which the low-refractive-index layer and the high-refractive-index layer are alternately repeated twice (the low-refractive-index layers 241 and 243 and the high-refractive-index layers 242 and 244) in the foregoing embodiment, the number of stack layers repeated may be increased. By increasing the number of stack layers, higher reflectance is obtained, and it becomes more advantageous from the viewpoints of improvement in light emitting efficiency and reduction of incidence of unnecessary light to the channel regions. It is sufficient to properly select the thicknesses and materials applied of the low-refractive-index layer and the high-refractive-index layer in accordance with a required reflection characteristic. In practice, with a structure obtained by stacking layers by repeating the combination of the low-refractive-index layer and the high-refractive-index layer three times (total six layers), a sufficient effect is obtained. For example, when three low-refractive-index layers made of SiO₂ (N is about 1.46) and each having a thickness of 75 nm and three high-refractive-index layers made of TiO₂ (N is about 2.3) and each having a thickness of 75 nm are alternately stacked, a sufficient effect is obtained. In any case, preferably, the low-refractive-index is positioned on the side of the substrate 111 (the side on which the drive transistor Tr1 and the write transistor Tr2 are provided) for the reason that unnecessary light incident on the layer-stack structure is easily reflected to the top face side (the side opposite to the drive transistor Tr1 and the write transistor Tr2).

Although the case where the first electrode layer 13 is an anode and the second electrode layer 16 is a cathode has been described in the foregoing embodiment, the first electrode layer 13 may be a cathode and the second electrode layer 16 may be an anode. Further, although the configuration of the organic light emitting elements 10R, 10G, and 10B has been concretely described in the foregoing embodiment, it is unnecessary to provide all of the layers and another layer may be further provided. For example, between the first electrode layer 13 and the organic layer 14, a hole injection thin film layer made of chromic oxide (III) (Cr₂O₃), ITO (Indium-Tin Oxide, an oxide mixed film of indium (In) and tin (Sn)), or the like may be provided.

In addition, the case where the second electrode layer 16 is constructed by a semi-transmissive reflection layer has been described in the foregoing embodiment. The second electrode layer 16 may have a structure in which a semi-transmissive reflection layer and a transparent electrode are stacked in order from the side of the first electrode layer 13. The transparent electrode is provided to decrease electric resistance of the semi-transmissive reflection layer and is made of a conductive material having translucency to light generated by the light emitting layer. The preferred material of the transparent electrode is, for example, a compound containing ITO or indium, zinc (Zn), and oxygen for a reason that excellent conductivity may be obtained even when film formation is performed at room temperature. The thickness of the transparent electrode may be set to, for example, 30 nm to 1000 nm both inclusive. In this case, a resonator structure may be formed by using the semi-transmissive reflection layer as one end part, providing another end part in a position opposite to the semi-transmission reflection layer while sandwiching the transparent electrode, and setting the transparent electrode as a resonation part. After providing such a resonator structure, the organic light emitting elements 10R, 10G, and 10B are covered with the protection film 18, and the protection film 18 is made of a material having a refractive index almost the same as that of the material of the transparent electrode. Such a configuration is preferable since the protection film 18 may be used as a part of the resonation part.

In addition, although the case of the active-matrix display device has been described in the foregoing embodiments, the present invention may be also applied to a passive-matrix display device. Further, the configuration of the pixel drive circuit for active matrix driving is not limited to that in the foregoing embodiments. As necessary, a capacitive element and a transistor may be added. In this case, according to a change in the pixel drive circuit, a necessary drive circuit may be provided in addition to the signal line drive circuit 120 and the scan line drive circuit 130.

The present application contains subject matter related to that disclosed in Japanese Priority Patent Application JP 2008-328161 filed in the Japan Patent Office on Dec. 24, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a plurality of light emitting elements arranged on a substrate and obtained by stacking a first electrode layer, an organic layer including a light emitting layer, and a second electrode layer in order; and
an insulating film for isolating the organic layer by the light emitting elements,
wherein the insulating film has a layer stack structure in which a first layer and a second layer having a refractive index higher than that of the first layer are alternately stacked.

2. The display device according to claim 1, wherein the layer stack structure is a four-layer structure obtained by alternately stacking the first and second layers twice.

3. The display device according to claim 1, further comprising a plurality of drive elements provided in a layer between the substrate and the light emitting elements and performing display driving of the light emitting elements on the basis of a video signal.

4. The display device according to claim 3, wherein the first electrode layer is isolated by the insulating film by the light emitting elements, and
the second electrode layer is provided commonly for the plurality of light emitting elements.

5. The display device according to claim 4, further comprising an auxiliary electrode layer provided so as to surround the first electrode layer and the organic layer in the plurality of light emitting elements in a layer stack plane and electrically connected to the second electrode layer so as to isolate the insulating film by the light emitting elements.

6. The display device according to any of claims 1 to 5, wherein the first layer is made of at least one of silicon oxide (SiO₂), aluminum fluoride (AlF₃), calcium fluoride (CaF₂), cerium fluoride (CeF₃), lanthanum fluoride (LaF₃), lithium fluoride (LiF), magnesium fluoride (MgF₂), neodymium fluoride (NdF₃), and sodium fluoride (NaF) and
the second layer is made of at least one of silicon nitride (Si₃N₄), aluminum oxide (Al₂O₃), chromium oxide (Cr₂O₃), gallium oxide (Ga₂O₃), hafnium oxide (HfO₂), nickel oxide (NiO), magnesium oxide (MgO), indium tin oxide (ITO), lanthanum oxide (La₂O₃), niobium oxide (Nb₂O₅), tantalum oxide (Ta₂O₅), yttrium oxide (Y₂O₃), tungsten oxide (WO₃), titanium monoxide (TiO), titanium dioxide (TiO₂), and zirconium oxide (ZrO₂).

7. A display device comprising:
a plurality of light emitting elements disposed on a substrate and obtained by stacking a first electrode layer, an organic layer including a light emitting layer, and a second electrode layer in order;
a drive transistor provided in a layer between the substrate and the light emitting element and performing display driving of the light emitting element on the basis of a video signal; and
an insulating film provided between the drive transistor and the light emitting element,
wherein the insulating film has a layer stack structure in which a first layer and a second layer having a refractive index higher than that of the first layer are alternately stacked.

8. The display device according to claim 7, wherein the insulating film covers the drive transistor so as to be in contact with a channel region of the drive transistor.

9. The display device according to claim 7, further comprising:
a retention capacitor provided for each of the light emitting elements; and
a write transistor provided between the substrate and the insulating film and writing the video signal into the retention capacitor.

10. The display device according to claim 9, wherein the insulating film covers the write transistor and the drive transistor so as to be in contact with channel regions of the transistors.

11. The display device according to claim 7, wherein the first layer is made of at least one of silicon oxide (SiO₂), aluminum fluoride (AlF₃), calcium fluoride (CaF₂), cerium fluoride (CeF₃), lanthanum fluoride (LaF₃), lithium fluoride (LiF), magnesium fluoride (MgF₂), neodymium fluoride (NdF₃), and sodium fluoride (NaF), and
the second layer is made of at least one of silicon nitride (Si₃N₄), aluminum oxide (Al₂O₃), chromium oxide (Cr₂O₃), gallium oxide (Ga₂O₃), hafnium oxide (HfO₂), nickel oxide (NiO), magnesium oxide (MgO), indium tin oxide (ITO), lanthanum oxide (La₂O₃), niobium oxide (Nb₂O₅), tantalum oxide (Ta₂O₅), yttrium oxide (Y₂O₃), tungsten oxide (WO₃), titanium monoxide (TiO), titanium dioxide (TiO₂), and zirconium oxide (ZrO₂).

12. The display device according to any of claims 7 to 11, wherein in the insulating film, the first layer is positioned closest to the side of the substrate.
